(19) United States
(12) Patent Application Publication
(10) Pub. No.: US 2015/0262674 A1
(43) Pub. Date: Sep. 17, 2015

(54) SEMICONDUCTOR MEMORY DEVICE AND MEMORY CONTROLLER

(71) Applicant: KABUSHIKI KAISHA TOSHIBA, Tokyo (JP)

(72) Inventor: Masanobu SHIRAKAWA, Chigasaki (JP)

(21) Appl. No.: 14/470,452

(22) Filed: Aug. 27, 2014

(30) Foreign Application Priority Data
Mar. 14, 2014 (JP) 2014-052706

(51) Int. Cl. G11C 16/08; G11C 16/04

(52) U.S. Cl. CPC G11C 16/08; G11C 16/0483

(57) ABSTRACT

A semiconductor memory device includes memory cells, word lines, and a row decoder. When program verification is performed on a memory cell that has been programmed, the row decoder transfers a first voltage to word lines that are electrically connected to gates of first memory cells. Also, when data is read, the row decoder selects a word line electrically connected to gates of selected memory cells, transfers the first voltage to non-selected word lines that are electrically connected to the first memory cells, and transfers a second voltage, which is higher than the first voltage, to non-selected word lines that are electrically connected to second memory cells.

### CROSS-REFERENCE TO RELATED APPLICATION

This application is based upon and claims the benefit of priority from Japanese Patent Application No. 2014-052706, filed on Mar. 14, 2014, the entire contents of which are incorporated herein by reference.

### FIELD

Embodiments described herein relate generally to a semiconductor memory device and a memory controller.

### BACKGROUND

A NAND flash memory in which memory cells are three-dimensionally arranged is known.

### DESCRIPTION OF THE DRAWINGS

FIG. 1 is a block diagram illustrating a memory system according to an embodiment.

FIG. 2 is a block diagram illustrating a semiconductor memory device according to the embodiment.

FIG. 3 is a circuit diagram illustrating a memory cell array according to the embodiment.

FIG. 4 is a cross-sectional view illustrating the memory cell array according to the embodiment.

FIG. 5 is a schematic diagram illustrating a write state table according to the embodiment.

FIG. 6 is a circuit diagram illustrating a string unit according to the embodiment.

FIG. 7 is a timing chart illustrating various signals when a write operation according to the embodiment is performed.

FIG. 8 is a graph illustrating the threshold distribution of the memory cells according to the embodiment.

FIG. 9 is a circuit diagram illustrating a NAND string according to the embodiment.

FIG. 10 is a circuit diagram illustrating a NAND string according to the embodiment.

FIG. 11 is a timing chart illustrating various signals when a read operation according to the embodiment is performed.

FIG. 12 is a circuit diagram illustrating a NAND string according to the embodiment.

FIG. 13 is a timing chart illustrating various signals when an erase operation according to the embodiment is performed.

FIG. 14 is a circuit diagram illustrating a NAND string according to the embodiment.

FIG. 15 is a circuit diagram illustrating a NAND string according to the embodiment.

FIG. 16 is a circuit diagram illustrating a NAND string according to the embodiment.

FIG. 17 is a circuit diagram illustrating a NAND string.

FIG. 18 is a circuit diagram illustrating a NAND string.

FIG. 19 is a circuit diagram illustrating a NAND string.

FIG. 20 is a circuit diagram illustrating a NAND string.

FIG. 21 is a schematic diagram illustrating information held in a write state table according to a modification example.

FIG. 22 is a circuit diagram illustrating the NAND string according to the modification example.

FIG. 23 is a circuit diagram illustrating the NAND string according to the modification example.

FIG. 24 is a circuit diagram illustrating the NAND string according to the modification example.

### DETAILED DESCRIPTION

The present embodiment now will be described more fully hereinafter with reference to the accompanying drawings, in which various embodiments are illustrated. In the drawings, the thickness of layers and regions may be exaggerated for clarity. Like numbers refer to like elements throughout. As used herein the term “and/or” includes any and all combinations of one or more of the associated listed items and may be abbreviated as “/”.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “having,” “includes,” “including” and/or variations thereof, when used in this specification, specify the presence of stated features, regions, steps, operations, elements, and/or components, but do not preclude the presence or addition of one or more other features, regions, steps, operations, elements, components, and/or groups thereof.

It will be understood that when an element such as a layer or region is referred to as being “on” or extending “onto” another element (and/or variations thereof), it may be directly on or extend directly onto the other element or intervening elements may also be present. In contrast, when an element is referred to as being “directly on” or extending “directly onto” another element (and/or variations thereof), there are no intervening elements present. It will also be understood that when an element is referred to as being “connected” or “coupled” to another element (and/or variations thereof), it may be directly connected or coupled to the other element or intervening elements may be present. In contrast, when an element is referred to as being “directly connected” or “directly coupled” to another element (and/or variations thereof), there are no intervening elements present.

It will be understood that, although the terms first, second, etc. may be used herein to describe various elements, components, regions, layers and/or sections, these elements, materials, regions, layers and/or sections should not be limited by these terms. These terms are only used to distinguish one element, material, region, layer or section from another element, material, region, layer or section. Thus, a first element, material, region, layer or section discussed below could be termed a second element, material, region, layer or section without departing from the teachings of the present invention.

Relative terms, such as “lower”, “back”, and “upper” may be used herein to describe one element's relationship to another element as illustrated in the Figures. It will be understood that relative terms are intended to encompass different orientations of the device in addition to the orientation depicted in the Figures. For example, if the structure in the Figure is turned over, elements described as being on the “backside” of substrate would then be oriented on “upper” surface of the substrate. The exemplary term “upper”, may therefore, encompass both an orientation of “lower” and “upper,” depending on the particular orientation of the figure. Similarly, if the structure in one of the figures is turned over, elements described as “below” or “beneath” other elements would then be oriented “above” the other elements. The exemplary terms “below” or “beneath” may, therefore, encompass both an orientation of above and below.

Embodiments are described herein with reference to cross sections and perspective illustrations that are schematic illustrations of embodiments. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated, typically, may be rounded. Thus, the regions illustrated in the figures are schematic in nature and their shapes are not intended to illustrate the precise shape of a region and are not intended to limit the scope of the present invention.

A semiconductor memory device which is capable of improving performance and a memory controller are provided.

In general, according to one embodiment, there is provided a semiconductor memory device including a plurality of memory cells that are stacked above a semiconductor substrate and are electrically connected in series, a plurality of word lines that are electrically connected to gates of the memory cells, and a row decoder that is electrically connected to the word lines. When data is read, the row decoder selects a word line, transfers a first voltage to non-selected word lines that are electrically connected to first memory cells, and transfers a second voltage, which is different from the first voltage, to non-selected word lines which are electrically connected to second memory cells.

Hereinafter, embodiments will be described with reference to the accompanying drawings. Meanwhile, common reference numerals are attached to components having the same functions and configurations in the description below.

A semiconductor memory device and a memory controller according to an embodiment will be described. Hereinafter, a 3-dimensional stacked NAND flash memory, in which memory cells are stacked on the upper side of a semiconductor substrate, will be described as an example of the semiconductor memory device.

### 1. CONFIGURATION

1. 1 Configuration of Memory System

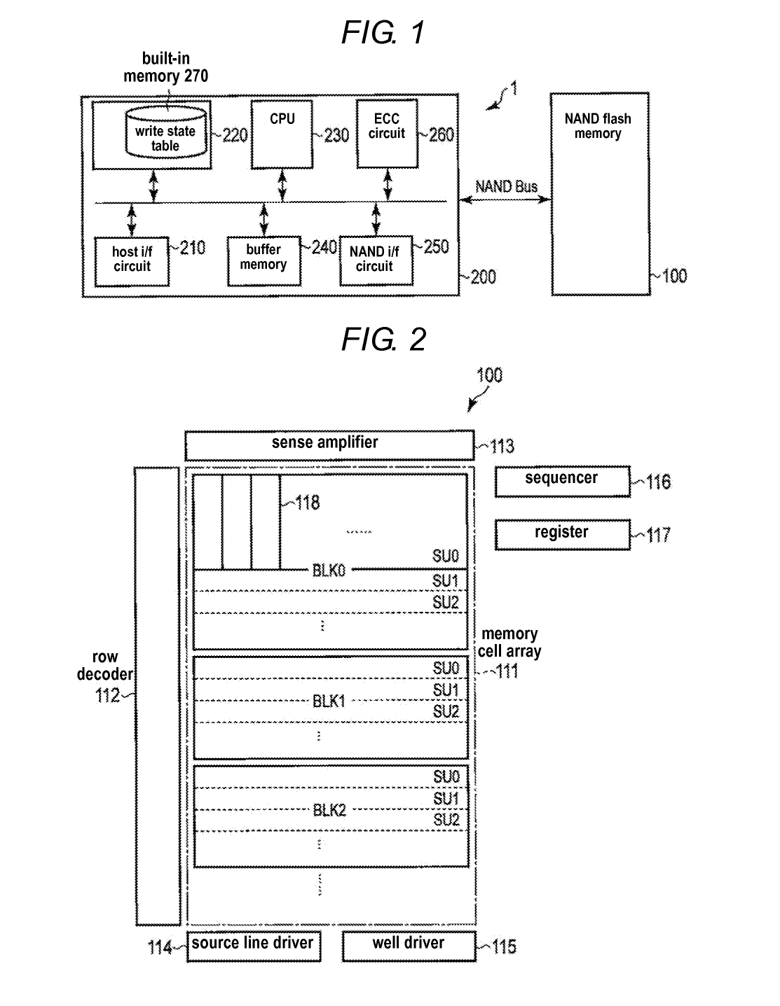

First, the configuration of a memory system which includes a semiconductor memory device according to an embodiment will be described with reference to FIG. 1. FIG. 1 is a block diagram illustrating the memory system according to the embodiment.

A memory system 1 includes a NAND flash memory 100 and a memory controller 200 as illustrated in the drawing. The controller 200 and the NAND flash memory 100 may form a single semiconductor device through, for example, the combination thereof. A memory card, such as an SD™ card, a Solid State Drive (SSD), or the like may be used as an example of the single semiconductor device.

The NAND flash memory 100 includes a plurality of memory cells, and stores data in a non-volatilization manner. The configuration of the NAND flash memory 100 will be described in detail below.

The controller 200 instructs the NAND flash memory 100 to perform read, write, erase, or the like in response to an instruction from external host equipment. In addition, the controller 200 manages a memory space of the NAND flash memory 100.

The controller 200 includes a host interface circuit 210, a built-in memory (RAM) 220, a processor (CPU) 230, a buffer memory 240, a NAND interface circuit 250, and an ECC circuit 260.

The host interface circuit 210 is connected to host equipment through a controller bus, and communicates with the host equipment. Further, the host interface circuit 210 transfers an instruction and data, which are received from the host equipment, the CPU 230 and the buffer memory 240, respectively. In addition, the host interface circuit 210 transfers data in the buffer memory 240 to the host equipment in response to the instruction of the CPU 230.

The NAND interface circuit 250 is connected to the NAND flash memory 100 through a NAND bus, and communicates with the NAND flash memory 100. Further, the NAND interface circuit 250 transfers the instruction, which is received from the CPU 230, to the NAND flash memory 100. In addition, when write is performed, the NAND interface circuit 250 transfers write data in the buffer memory 240 to the NAND flash memory 100. Further, when data is read, the NAND interface circuit 250 transfers data which is read from the NAND flash memory 100 to the buffer memory 240.

The CPU 230 controls the entire operation of the controller 200. For example, when the CPU 230 receives a write instruction from the host equipment, the CPU 230 issues the write instruction based on the NAND interface in response thereto. The CPU 230 performs the same operation when data is read or the data is erased. In addition, the CPU 230 performs various processes, such as wear leveling, in order to manage the NAND flash memory 100. Further, the CPU 230 performs various calculations. For example, the CPU 230 performs a data encryption process, a randomization process, and the like.

The ECC circuit 260 performs a data Error Checking and Correcting (ECC) process. That is, when data is written, the ECC circuit 260 generates parity data based on write data. When data is read, the ECC circuit 260 detects an error by generating a syndrome from the parity data, and corrects the error. Meanwhile, the CPU 230 may include the function of the ECC circuit 260.

The built-in memory 220 is, for example, a semiconductor memory such as a DRAM, and is used as the work area of the CPU 230. Further, the built-in memory 220 holds firmware, various management tables, and the like in order to manage the NAND flash memory 100. In addition, the built-in memory 220 holds a write state table 270 which is related to the NAND flash memory 100. The write state table 270 is information indicative of a page up to which data is written in a string unit SU which will be described later. Further, the CPU 230 issues a data read instruction or an erase instruction with reference to the information in the write state table 270. The write state table 270 will be described in detail in a category of 1.3.

1.2 Configuration of NAND Flash Memory

Subsequently, the configuration of the NAND flash memory 100 will be described.

1. 2. 1 Configuration of NAND Flash Memory 100

FIG. 2 is a block diagram illustrating the NAND flash memory 100 according to the embodiment. The NAND flash memory 100 includes a memory cell array 111, a row decoder 112, a sense amplifier 113, a source line driver 114, a well driver 115, a sequencer 116, and a register 117 as illustrated in the drawing.

The memory cell array 111 includes a plurality of blocks BLK (BLK0, BLK1, BLK2, . . . ) each of which is a set of a plurality of nonvolatile memory cells associated with word lines and bit lines. The block BLK is a data erase unit, and data in the same block BLK is collectively erased. Each block BLK includes a plurality of string units SU (SU0, SU1, SU2, . . . ) each of which is a set of NAND strings 118 in which the memory cells are connected in series. It is apparent that the number of blocks in the memory cell array 111 and the number of string units in a single block BLK are arbitrary.

The row decoder 112 decodes a block address or a page address, and selects any one of word lines of a relevant block. Further, the row decoder 112 applies an appropriate voltage to the selected word line and non-selected word lines.

When data is read, the sense amplifier 113 senses and amplifies data read to a bit line from the memory cells. In addition, when data is written, the sense amplifier 113 transfers the write data to the memory cells. The data is read from and written to the memory cell array 111 in units of a plurality of memory cells, and the units form a page.

The source line driver 114 applies a voltage to source lines.

The well driver 115 applies a voltage to a well region in which the NAND strings 118 is formed.

The register 117 holds various data. For example, the register 117 holds the statuses of the data write and erase operations that indicate whether or not the operation of the controller is normally completed. Otherwise, the register 117 holds a command, an address, and the like which is received from the controller 200. In addition, the register 117 may hold various tables.

The sequencer 116 controls the entire operation of the NAND flash memory 100.

1.2.2 Memory Cell Array 111

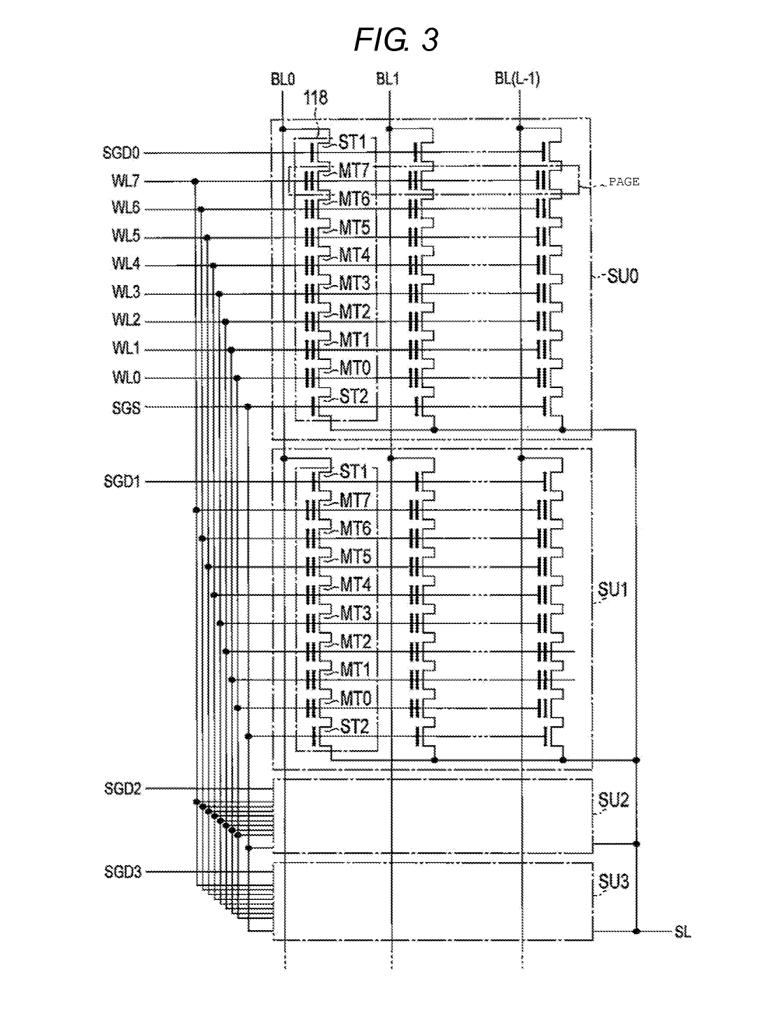

Subsequently, the configuration of the memory cell array 111 will be described in detail. FIG. 3 is a circuit diagram illustrating any one of the blocks BLK and other blocks BLK have the same configuration.

As illustrated in the drawing, the block BLK includes, for example, four string units SU (SU0 to SU3). In addition, each of the string units SU includes a plurality of NAND strings 118.

Each of the NAND strings 118 includes, for example, eight memory cell transistors MT (MT0 to MT7), and select transistors ST1 and ST2. Each of the memory cell transistors MT includes a stacked gate, which has a control gate and a charge storage layer, and holds data in non-volatile manner. Meanwhile, the number of memory cell transistors MT is not limited to eight, and may be 16, 32, 64, 128, or the like, that is, is not limited to any particular number. The memory cell transistors MT are arranged between the select transistors ST1 and ST2 such that the current paths thereof are connected in series. The current path of the memory cell transistor MT7 which is on one end side of the serial connection is connected to one end of the current path of the select transistor ST1, and the current path of the memory cell transistor MT0 which is on the other end side is connected to one end of the current path of the select transistor ST2.

The gates of the select transistors ST1 of the respective string units SU0 to SU3 are connected to respective select gate lines SGD0 to SGD3. In contrast, the gates of the select transistors ST2 are commonly connected to the same select gate line SGS between the plurality of string units. In addition, the control gates of the respective memory cell transistors MT0 to MT7 in the same block BLK0 are commonly connected to word lines WL0 to WL7, respectively.

That is, the word lines WL0 to WL7 and the select gate line SGS are commonly connected between the plurality of string units SU0 to SU3 in the same block BLK. In contrast, the select gate lines SGD are independent from each other for the respective string units SU0 to SU3 even in the same block BLK.

In addition, from among the NAND strings 118 which are arranged in a matrix shape in the memory cell array 111, the other ends of the current paths of the select transistors ST1 of the NAND strings 118 in the same row are commonly connected to any one of bit lines BL (BL0 to BL(L−1), (L−1) is a natural number which is equal to or greater than 1). That is, the bit lines BL commonly connect the NAND strings 118 between the plurality of blocks BLK. In addition, the other ends of the current paths of the select transistors ST2 are commonly connected to a source line SL. The source line SL is commonly connected to, for example, the NAND strings 118 between the plurality of blocks.

As described above, the data of the memory cell transistors MT in the same block BLK is collectively erased. In contrast, data is collectively read and written with regard to the plurality of memory cell transistors MT which are commonly connected to any one of the word lines WL in any one of the string units SU of any one of the blocks BLK. The unit of reading and writing is called a “page”.

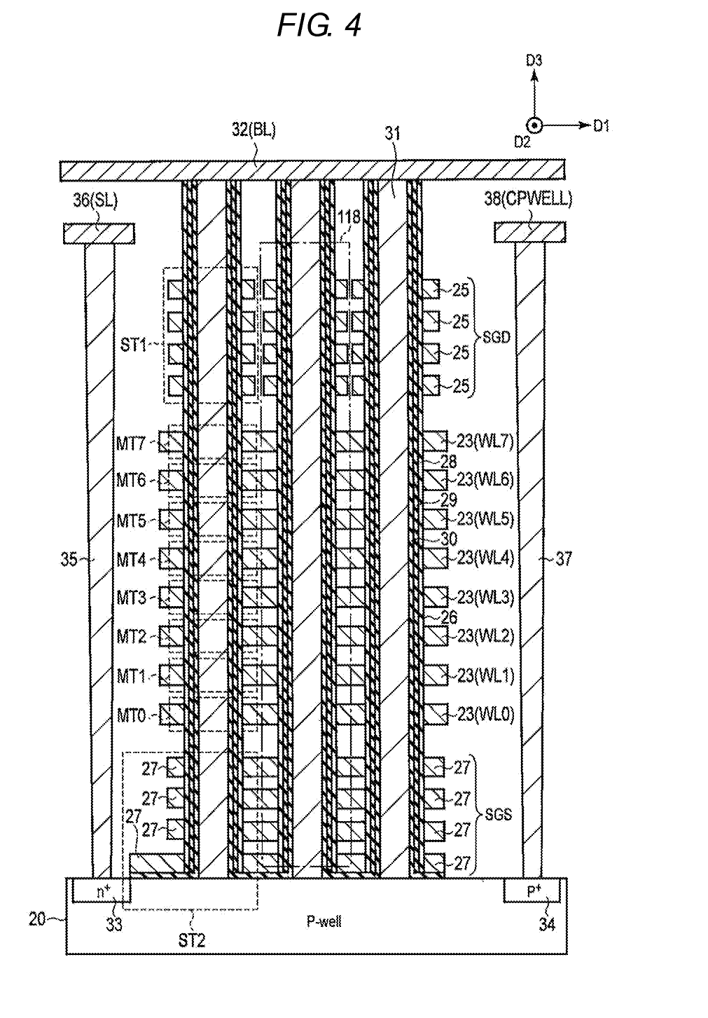

FIG. 4 is a cross-sectional view illustrating a partial area of the memory cell array 111 according to the embodiment. As illustrated in the drawing, the plurality of NAND strings 118 are formed on a p-type well region 20. That is, on the well region 20, a plurality of wire layers 27 which function as the select gate lines SGS, a plurality of wire layers 23 which function as the word lines WL, and a plurality of wire layers 25 which function as the select gate lines SGD are formed.

Further, a memory hole 26 which reaches the well region 20 through the wire layers 25, 23, and 27 is formed. A block insulating film 28, a charge storage layer 29 (insulating film), and a gate insulating film 30 are sequentially formed on the side surface of the memory hole 26. Further, a conductive film 31 is embedded in the memory hole 26. The conductive film 31 functions as the current path of the NAND string 118, and forms the channel area when the memory cell transistors MT and the select transistors ST1 and ST2 are operated.

In each NAND string 118, the wire layers 27 which are provided in plural (in the example, 4 layers) are electrically connected in common and are connected to the same select gate line SGS. That is, the four-layered wire layers 27 substantially function as a gate electrode of a single select transistor ST2. This is the same as in the select transistor ST1 (four-layered select gate line SGD).

In such a configuration, in each NAND string 118, the select transistor ST2, the plurality of memory cell transistors MT, and the select transistor ST1 are sequentially stacked on the well region 20.

Meanwhile, in the example of FIG. 4, the select transistors ST1 and ST2 include the charge storage layers 29 similarly to the memory cell transistors MT. However, the select transistors ST1 and ST2 do not substantially function as memory cells which hold data but function as switches. At this time, thresholds which cause the select transistors ST1 and ST2 to be turned on or off may be controlled by injecting charges into the charge storage layer 29.

A wire layer 32 which functions as the bit line BL is formed on the upper end of the conductive film 31. The bit line BL is connected to the sense amplifier 113.

Further, an n⁺ dopant diffusion layer 33 and a p⁺ dopant diffusion layer 34 are formed on the surface of the well region 20. A contact plug 35 is formed on the diffusion layer 33, and a wire layer 36 which functions as the source line SL is formed on the contact plug 35. The source line SL is connected to the source line driver 114. In addition, a contact plug 37 is formed on the diffusion layer 34, and a wire layer 38 which functions as a well wiring CPWELL is formed on the contact plug 37. The well wiring CPWELL is connected to the well driver 115. The wire layers 36 and 38 are formed on a layer which is an upper layer than the select gate line SGD and is a lower layer than the wire layer 32.

The above configuration is arranged in plural in the depth direction of a paper in which FIG. 4 is illustrated, and the string units SU are formed by sets of the plurality of NAND strings 118 which are arranged in the depth direction. In addition, the wire layers 27, which function as the plurality of select gate lines SGS included in the same string unit SU, are commonly connected to each other. That is, the gate insulating film 30 is formed even on the well region 20 between the adjacent NAND strings 118, the wire layer 27 and the gate insulating film 30 which are adjacent to the diffusion layer 33 are formed up to the vicinity of the diffusion layer 33.

Therefore, when the select transistor ST2 is caused to be an on state, the channel thereof electrically connects the memory cell transistor MT0 to the diffusion layer 33. In addition, it is possible to give a potential to the conductive film 31 by applying a voltage to the well wiring CPWELL.

Meanwhile, other configurations may be used as the configuration of the memory cell array 111. That is, the configuration of the memory cell array 111 is disclosed in, for example, U.S. patent application Ser. No. 12/407,403 “Three dimensional stacked nonvolatile semiconductor memory” which is applied Mar. 19, 2009, U.S. patent application Ser. No. 12/406,524 “Three dimensional stacked nonvolatile semiconductor memory” which is applied Mar. 18, 2009, U.S. patent application Ser. No. 12/679,991 “Non-volatile semiconductor storage device and method of manufacturing the same” applied Mar. 25, 2010, and U.S. patent application Ser. No. 12/532,030 “Semiconductor memory and method for manufacturing the same” which is applied Mar. 23, 2009. All of the patent applications are incorporated by reference herein.

1.3 Write State Table 270

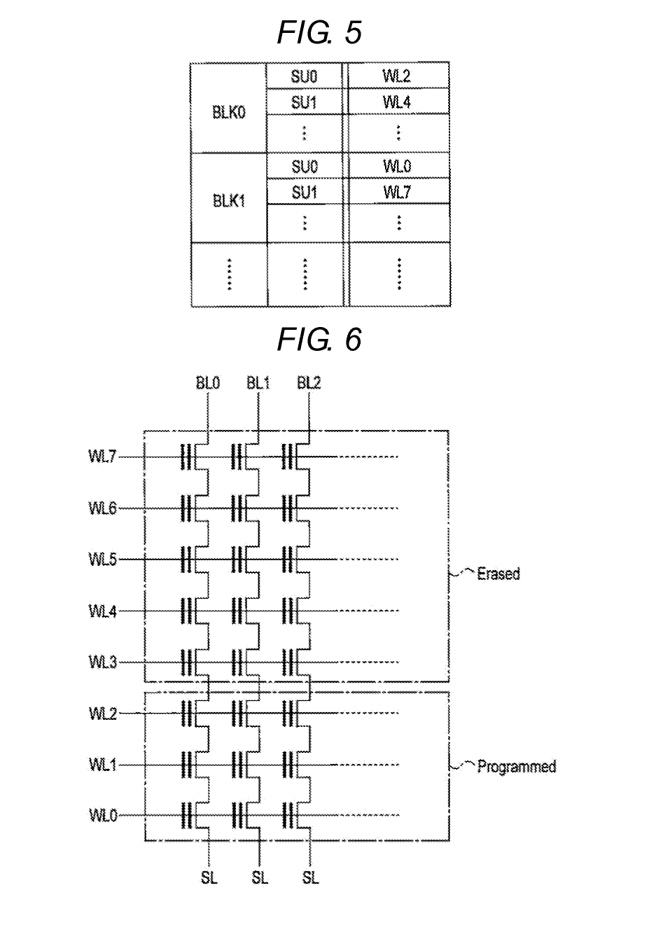

Subsequently, the write state table 270 illustrated in FIG. 1 will be described. FIG. 5 is a schematic diagram illustrating the write state table 270.

As illustrated in the drawing, the table 270 holds information indicative of word lines WL (in other words, a page) to which the data is written in each string unit SU of each block BLK. Normally, in the NAND flash memory, data is sequentially written from a source-side memory cell transistor MT. Therefore, the example of FIG. 5 illustrates that data is written in the memory cell transistors which are connected to the word lines WL0 to WL2 in the string unit SU0 of the block BLK0, and that the memory cell transistors which are connected to the word lines WL3 to WL7 are in an erase state. The situation is illustrated in FIG. 6. In addition, in the string unit SU1 of the block BLK1, it is illustrated that data is written in the word lines WL0 to WL7, that is, in the whole memory cell transistors MT.

The CPU 230 of the memory controller 200 updates the write state table 270 whenever data is written in the NAND flash memory 100 or whenever data is copied between the blocks.

### 2. DATA WRITE OPERATION

Subsequently, a data write operation according to the embodiment will be described.

2.1 Signals on NAND Bus

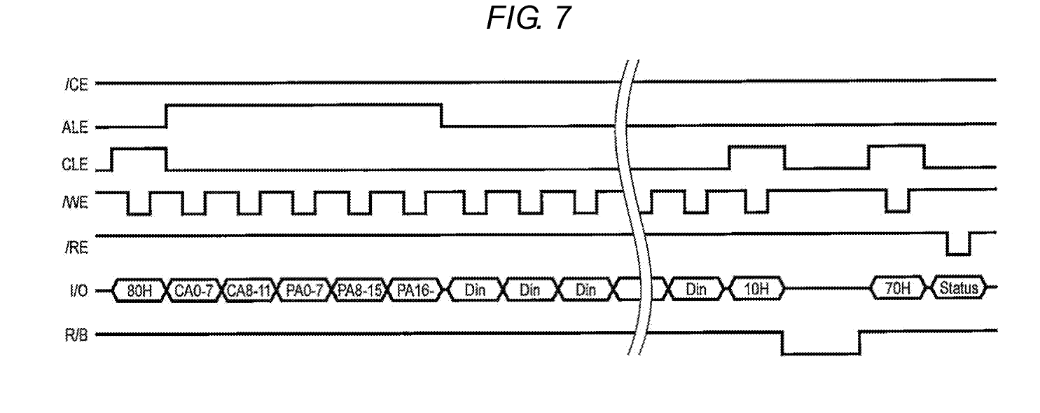

First, signals which are transmitted and received on the NAND Bus between the NAND flash memory 100 and the controller 200 will be described with reference to FIG. 7. FIG. 7 is a timing chart illustrating various signals acquired when data is written. In the drawing, a chip enable signal /CE, an address latch enable signal ALE, a command latch enable signal CLE, a write enable signal /WE, a read enable signal /RE, an input/output signal I/O, and a ready/busy signal R/B are signals which are transmitted and received between the controller 200 and the NAND flash memory 100.

/CE is a signal for enabling the NAND flash memory 100, and is enabled and asserted at a Low level. ALE is a signal for providing a notification that an input signal is an address signal to the NAND flash memory. CLE is a signal for providing a notification that the input signal is a command to the NAND flash memory. /WE is a signal for causing the input signal to be supplied to the NAND flash memory 100. The signal R/B is a signal for indicating whether the NAND flash memory 100 is in a ready state (state in which a signal may be received) or in a busy state (state in which it cannot receive a signal) for the controller 200.

As illustrated in the drawing, the controller 200 first issues a write command “80H” and asserts CLE (“H” level). Subsequently, the controller 200 issues column addresses (CA0 to CA11) for two cycles, and asserts ALE (“H” level). Sequentially, the controller 200 issues page addresses (PA0 to PA16) for three cycles. The command and addresses are stored, for example, in the register 117 of the NAND flash memory 100.

Thereafter, the controller 200 outputs data Din for a plurality of cycles. Meanwhile, ALE and CLE are negated (“L” level). At last, the controller 200 issues a write command “10H” and asserts CLE. Whenever the controller 200 issues a command, an address, data and the like, the controller 200 asserts /WE. Accordingly, whenever /WE is toggled, the signals are supplied to the NAND flash memory 100.

The NAND flash memory 100 starts a write operation in response to the command “10H” and is in a busy state (R/B=“L”).

If the write operation is completed in the NAND flash memory 100, R/B returns to an “H” level. Thereafter, the controller 200 issues a status read command “70H”, and reads status, which indicates whether or not data is successfully written, from the register 117.

2.2 Threshold Distribution

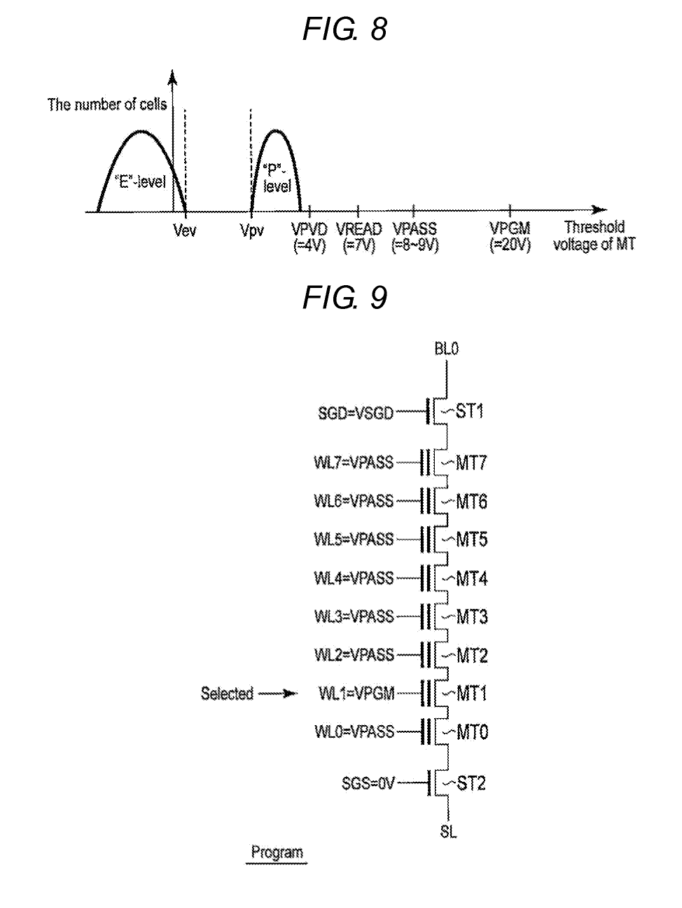

FIG. 8 is a graph illustrating the threshold distribution of the memory cell transistor MT. In the example, an example in which the memory cell transistor is capable of holding data of one bit (2 values) is described. However, the memory cell transistor may be capable of holding data of two bits (4 values) or more.

As illustrated in the drawing, the thresholds of the memory cell transistors MT in the erase state are smaller than those in an erase verification level Vev, and may be negative values or positive values. The thresholds of the memory cell transistors MT in the write state are greater than those in a program verification level Vpv (Vpv>Vev), and have, for example, a positive value.

When data is written and read, a voltage VPVD (for example, 4 V), VREAD (for example, 7V), VPASS (for example, 8 to 9 V), and VPGM (for example, 20 V), or the like is used, and there is a relationship in which Vpv<VPVD<VREAD<VPASS<VPGM.

2.3 Operation of NAND Flash Memory 100

Subsequently, an operation of the NAND flash memory 100 when the write operation is performed will be described. The write operation generally includes a programming operation to raise thresholds by injecting charge into the charge storage layer, and a program verification operation to recognize thresholds which change as a result of the programming operation. Further, data is written in a page unit by repeating a set of the operations. The operations are mainly performed under the control of the sequencer 116. Meanwhile, an operation to maintain the thresholds of the memory cell transistors MT at an “E” level is called a “1” write, and an operation to raise the thresholds from the “E” level to a “P” level is called a “0” write.

FIG. 9 is a circuit diagram illustrating the NAND string 118 when programming is performed. As illustrated in the drawing, the row decoder 112 applies the voltage VPGM to a selected word line WL1 and applies the voltage VPASS to the other non-selected word lines WL0 and WL2 to WL7. VPGM is a high voltage for injecting charge into the charge storage layer through FN tunneling, and VPASS is a voltage which is capable of suppressing the non-selected memory cell transistors from being erroneously written in the NAND string which is a target to be written with “0”, and is capable of boosting a voltage of a channel due to coupling to the extent that the thresholds in the selected memory cell transistors MT are suppressed from rising in the NAND string in a state in which “1” is written.

In addition, the row decoder 112 causes the select transistor ST2 to be turned off by applying 0 V to the select gate line SGS. In addition, the row decoder 112 applies VSGD to the select gate line SGD. As a result, in a bit line BL (for example, 0 V is given) in which “0” is written, the select transistor ST1 is in an on state, and the potential of the bit line is transferred to the channels of the memory cell transistors MT. Therefore, data is programmed in the selected memory cell transistor MT1. In the bit line BL on the other side in which “1” is written (for example, positive potential is given), the select transistor ST1 is in a cut-off state. As a result, the channels of the memory cell transistors MT are in an electrically floating state, and the data is not programmed.

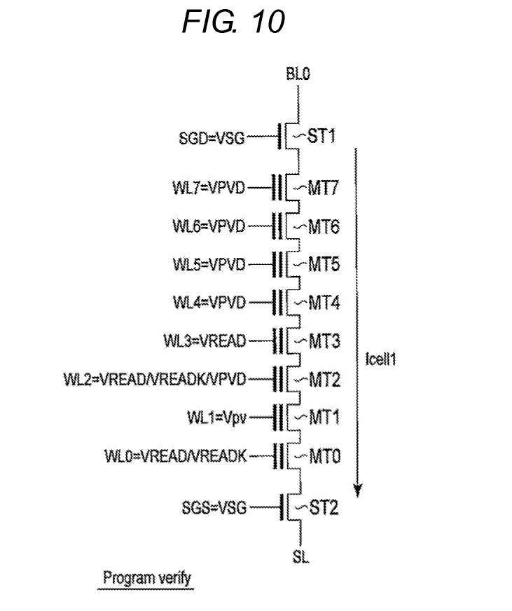

FIG. 10 is a circuit diagram illustrating the NAND string 118 acquired when program verification is performed. As illustrated in the drawing, the row decoder 112 applies a program verification voltage Vpv to the selected word line WL1, applies a voltage VREAD or VREADK to the non-selected word line WL0 which has been already programmed, applies a voltage VREAD, VREADK, or VPVD to the non-selected word line WL2, applies a voltage VREAD to the non-selected word line WL3, and applies the voltage VPVD to the other non-selected word lines WL4 to WL7. VREAD and VPVD are voltages for causing the memory cell transistors MT to be turned on regardless of held data, and there is a relationship in which VREAD>VPVD. Although VREADK is normally greater than VREAD, VREADK may be smaller than VREAD. VREADK is a voltage for preventing erroneous read due to word lines which are come into contact with the selected word line.

A further detailed example of a voltage, which is applied to the word lines WL when the program verification is performed, will be described below. For example, it is assumed that the number of word lines in the string unit SU is N+1 (N is a natural number which is equal to or greater than 6) and WLn (n is any one of 0 to N) is a selected word line.

In this case, a program verification voltage Vpv is applied to the word line WLn. Further, VREAD or VREADK is applied to a word line WL (n−1) which is on a further source side than the selected word line WLn, and VREAD is applied to word lines WL0 to WL (n−2).

On the other hand, VREAD or VREADK is applied to a word line WL(n+1) which is on a further drain side than the selected word line WLn, VREAD is applied to WL(n+2), and VPVD is applied to WL(n+3) to WLN.

In addition, the row decoder 112 applies VSG to the select gate lines SGD and SGS, and causes the select transistors ST1 and ST2 to be turned on. As a result, if the memory cell transistor MT1 which is connected to the selected word line WL1 is turned on, cell current Icell1 flows from the bit line BL to the source line SL. The sense amplifier 113 performs sense amplification on the cell current and reads data.

### 3. DATA READ OPERATION

Subsequently, a data read operation according to the embodiment will be described.

3.1 Signals on NAND Bus

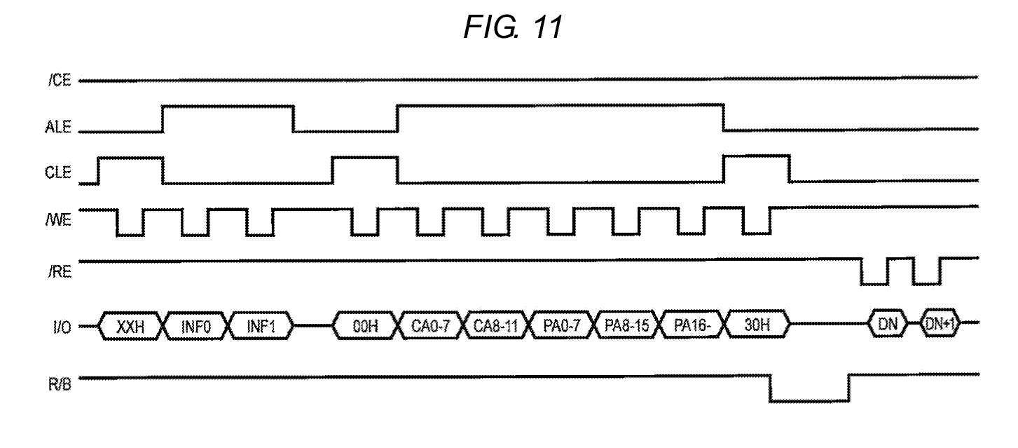

First, signals which are transmitted and received on the NAND bus between the NAND flash memory 100 and the controller 200 will be described with reference to FIG. 11. FIG. 11 is a timing chart illustrating various signals acquired when data is read.

As illustrated in the drawing, the controller 200 first issues a write state transmission command “XXH” and asserts CLE. Sequentially, the CPU 230 of the controller 200 reads information indicative of a word line WL (in other words, page), in which data is written, in the string unit SU which is a read target with reference to the write state table in the built-in memory 220, and transfers the information (“INF0” and “INF1”) to the NAND flash memory 100. Meantime, the signal ALE is asserted. The pieces of information “INF0” and “INF1” are stored in, for example, the register 117.

Thereafter, the controller 200 issues a read command “00H” and asserts CLE. Subsequently, the controller 200 issues a column address and a page address as the same as when the write operation is performed. The command and the address are also stored in, for example, the register 117. Further, the controller 200 issues a read command “30H” at last.

The NAND flash memory 100 starts the read operation in response to the command “30H”, and is in the busy state (R/B=“L”).

Thereafter, if the NAND flash memory 100 returns to a ready state, read data is transferred from the NAND flash memory 100 to the controller 200 whenever /RE is asserted.

3.2 Operation of NAND Flash Memory 100

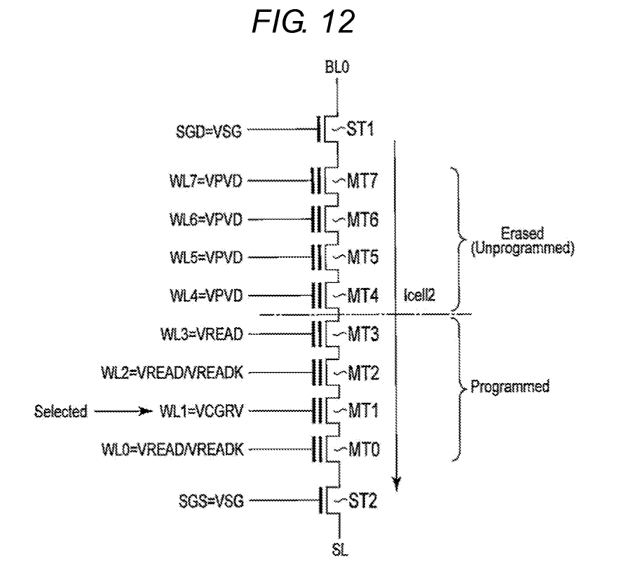

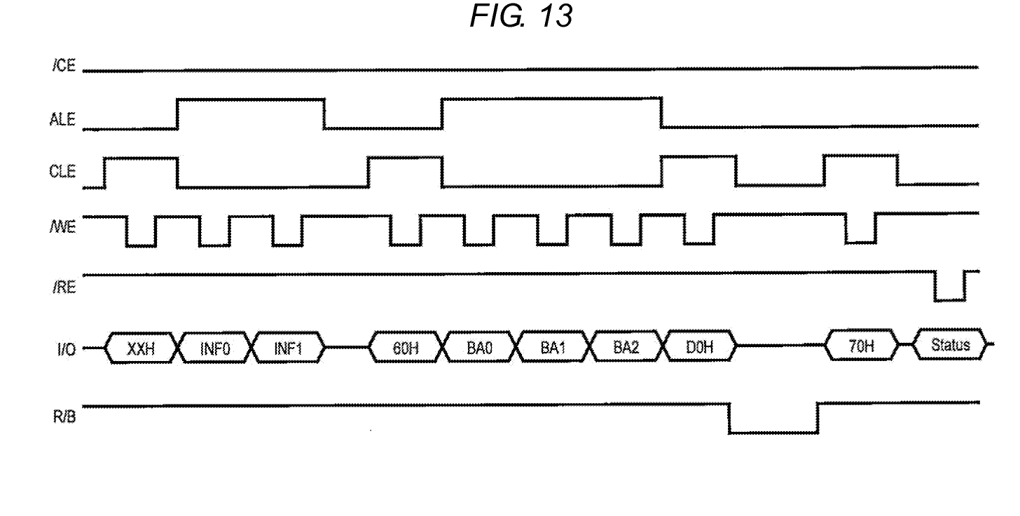

Subsequently, the operation of the NAND flash memory 100 when the read operation is performed will be described. FIG. 12 is a circuit diagram illustrating the NAND string 118 when the read operation is performed. FIG. 12 illustrates a case in which data has been already written in the memory cell transistors MT which are connected to the word lines WL0 to WL3, and in which data has not been written yet in the memory cell transistors MT which are connected to the word lines WL4 to WL7 (erase state).

As illustrated in the drawing, the row decoder 112 applies a voltage VCGRV to a selected word line WL1. VCGRV is a voltage for reading data from the selected memory cell. In addition, the row decoder 112 applies a voltage VREAD or VREADK to non-selected word lines WL0 and WL2 in which data has been already written, and applies a voltage VREAD to the word line WL3. Further, the row decoder 112 applies a voltage VPVD, which is used when program verification is performed, to the word lines WL4 to WL7 in which data has not been written yet. It is possible to determine a word line WL, to which the VREAD is applied, and a word line WL, to which the VPVD is applied, is such a way that, for example, the sequencer 116 refers to the information “INF0” and “INF1” in the register 117.

Further, the row decoder 112 applies VSG to the select gate lines SGD and SGS, and causes the select transistors ST1 and ST2 to be turned on. As a result, if the memory cell transistor MT1 which is connected to the selected word line WL1 is turned on, cell current Icell2 flows from the bit line BL to the source line SL. The sense amplifier 113 senses and amplifies the cell current, and reads data.

A further detailed example of a voltage, which is applied to the word line WL when the read operation is performed will be described below. For example, it is assumed that the number of word lines in the string unit SU is N+1 (N is a natural number which is equal to or greater than 6), WLn (n is any one of 0 to N) is a selected word line, and data is written in word lines WL0 to WLm (m is a natural number which is equal to or greater than n, n<<m).

In this case, a read voltage VCGRV is applied to the word line WLn. Further, VREAD or VREADK is applied to word lines WL(n−1) and WL(n+1) which are adjacent to the selected word line WLn, VREAD is applied to word lines WL0 to WL(n−2) and a word line WL(n+2), VREAD is applied to word lines WL(n+3) to WLm, and VPVD is applied to word lines WL(m+1) to WLN.

### 4. DATA ERASE OPERATION

Subsequently, a data erase operation according to the embodiment will be described.

4.1 Signals on NAND Bus

First, signals which are transmitted and received on the NAND bus between the NAND flash memory 100 and the controller 200 will be described with reference to FIG. 13. FIG. 13 is a timing chart illustrating various signals acquired during a data erase operation.

As illustrated in the drawing, the controller 200 first transfers a write state transmission command “XXH” and information “INF0” and “INF1” to the NAND flash memory 100 as the same as when data is read.

Thereafter, the controller 200 issues an erase command “60H” and transfers the block address of the block BLK which is an erase target. The command and the address are also stored in, for example, the register 117. Further, the controller 200 issues an erase command “D0H” at last.

The NAND flash memory 100 starts a read operation in response to the command “D0H” and is in a busy state (R/B=“L”).

If the write operation is completed in the NAND flash memory 100, R/B returns to the “H” level. Thereafter, the controller 200 issues a status read command “70H” and reads a status, which indicates whether or not the data is successfully erased, from the register 117.

4.2 Operation performed by NAND Flash Memory 100

Subsequently, an operation performed by the NAND flash memory 100 when the erase operation is performed will be described. The erase operation generally includes a data erase operation to lower the thresholds by abstracting charges from the charge storage layer or injecting a hole into the charge storage layer, and an erase verification operation to recognize change in the threshold distribution as a result of the data erase operation. Further, the data is erased, for example, in a block unit (or a string unit or the like) by repeating a set of the operations.

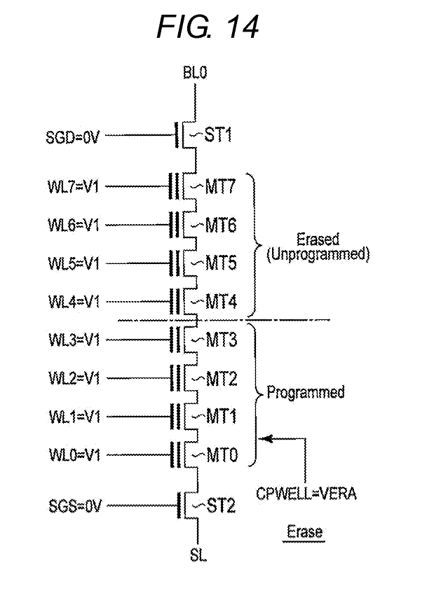

FIG. 14 is a circuit diagram illustrating the NAND string 118 when data is erased. FIG. 14 illustrates a case in which data has been already written in the memory cell transistors MT connected to the word lines WL0 to WL3 and in which data has not been written yet in the memory cell transistors MT connected to the word lines WL4 to WL7 (has been already in an erase state).

As illustrated in the drawing, the row decoder 112 applies a voltage V1 (for example, 0 V) to all of the word lines WL0 to WL7. In addition, the well driver 115 applies an erase voltage VERA (a positive voltage of, for example, 20 V) to the well region 20. As a result, charges in the charge storage layer are drawn to the conductive film 31, and thus the thresholds of the memory cell transistors MT are lowered.

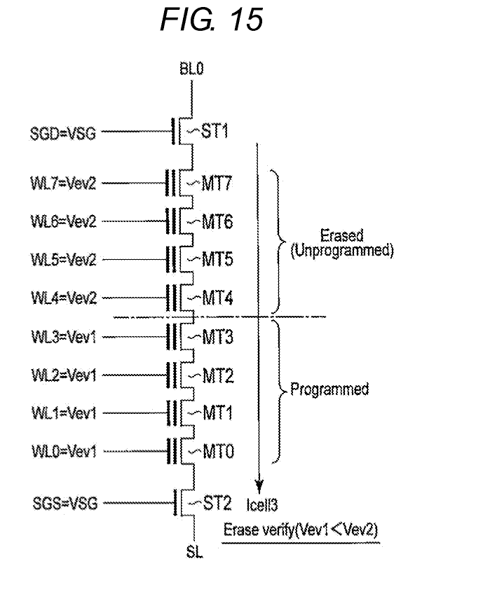

FIG. 15 is a circuit diagram illustrating the NAND string 118 when erase verification is performed. As illustrated in the drawing, the row decoder 112 applies an erase verification voltage Vev1 to non-selected word lines WL0 to WL3 in which data has been already written. Further, the row decoder 112 applies an erase verification voltage Vev2 (<Vev1) to word lines WL4 to WL7 in which data has not been written yet. It is possible to determine a word line WL to which Vev1 is applied and a word line WL to which Vev2 is applied in such a way that, for example, the sequencer 116 refers to the information “INF0” and “INF1” of the register 117.

Further, the row decoder 112 causes the select transistors ST1 and ST2 to be turned on by giving VSG to the select gate lines SGD and SGS. As a result, if all of the memory cell transistors MT0 to MT7 which are connected to the word lines WL0 to WL7 are turned on, that is, if the thresholds of the memory cell transistors MT are lowered to a desired value, cell current Icell3 flows from the bit line BL to the source line SL. The sense amplifier 113 senses and amplifies the cell current and reads data.

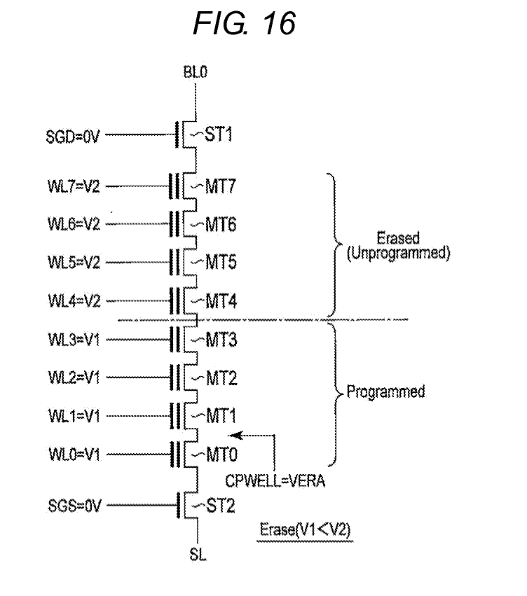

Meanwhile, in the data erase operation which is described with reference to FIG. 14, the voltage which is applied to the word line WL may be changed according to whether or not write was completed. Such an example is illustrated in FIG. 16. FIG. 16 is a circuit diagram illustrating the NAND string 118 acquired when the data erase operation is performed. As illustrated in the drawing, the row decoder 112 may apply the voltage V1 to non-selected word lines WL0 to WL3 in which data has been already written, and may apply the voltage V2 (>V1) to word lines WL4 to WL7.

### 5. ADVANTAGES ACCORDING TO EMBODIMENT

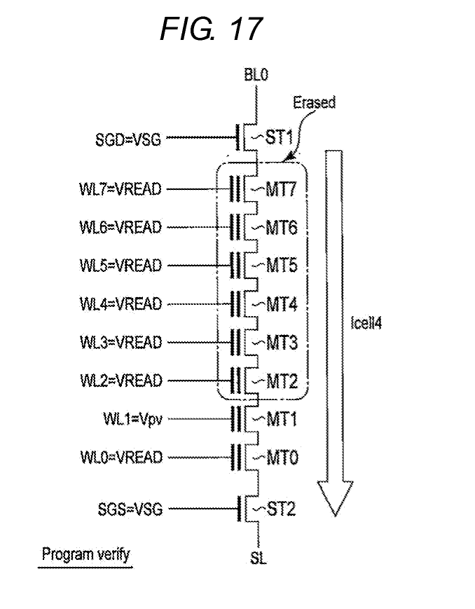

As described above, in the semiconductor memory device according to the embodiment, a voltage, which is applied to the word line WL when the write operation and the erase operation are performed, is set according to a word line of the NAND string 118 to which data is written. Therefore, it is possible to improve the performance of the NAND flash memory. Hereinafter, the advantages will be described with reference to FIGS. 17 to 20. FIGS. 17 to 20 are circuit diagrams illustrating the NAND string.

When the program verification is performed, an application voltage which is generally considered is as illustrated in FIG. 17. That is, VREAD is applied to all of the non-selected word lines WL. In this case, for example, when the memory cell transistor MT1 is a write target, the memory cell transistors which are connected to the memory cell transistors MT2 to MT7 on the further drain side are in the erase state. That is, since the thresholds of the memory cell transistors MT2 to MT7 are sufficiently low, relatively high cell current Icell4 flows.

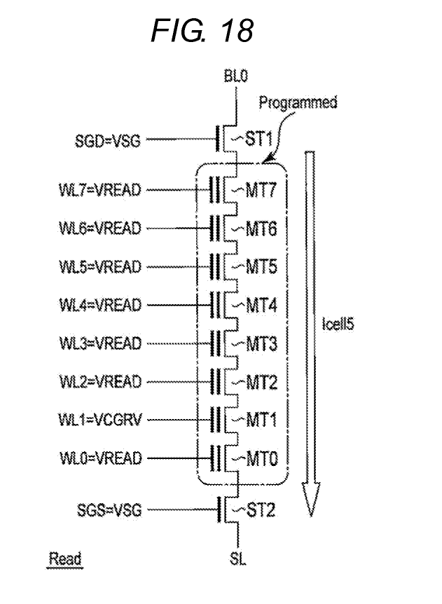

Subsequently, FIG. 18 illustrates a situation in which data is read from the memory cell transistor MT1 after data is written in the memory cell transistors MT2 to MT7. In this case, the situation of FIG. 18 is different from that of FIG. 17 in that most of the thresholds of the non-selected memory cell transistors MT2 to MT7, which are on the further drain side than the memory cell transistor MT1, are greater than those in the erase state (according to a write pattern). Therefore, the memory cell transistors MT2 to MT7 are weakly turned on compared to the case illustrated in FIG. 17. Therefore, the flowing cell current Icell5 is smaller than the cell current Icell4 which flows when the program verification is performed.

If so, regardless that the memory cell transistor MT1 passes the program verification, there is a possibility that the memory cell transistor MT1 is determined to be an off-cell when data is read. That is, there is a possibility that it is hard to correctly read the data due to the difference in situations when the program verification is performed and when data is read.

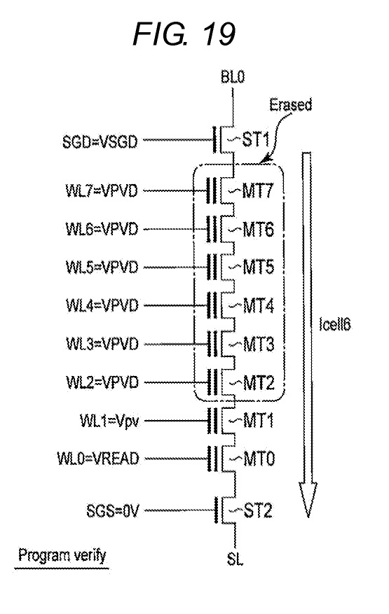

Here, a method illustrated in FIG. 19 may be considered. If the method of FIG. 19 is used, VPVD which is lower than the voltage VREAD is applied to the word lines WL2 to WL7 which are connected to the memory cell transistors MT2 to MT7 in the erase state when the program verification is performed. If so, the gate potential of the memory cell transistors MT2 to MT7 is lowered compared to the case in FIG. 17, with the result that the flowing cell current Icell6 is smaller than Icell4, and thus it is possible to set flowing cell current Icell6 to approximately the same degree as Icell5. That is, if cell current, which flows when the program verification is performed, and cell current, which flows when data is read, are set to the same degree, it is possible to correctly read data.

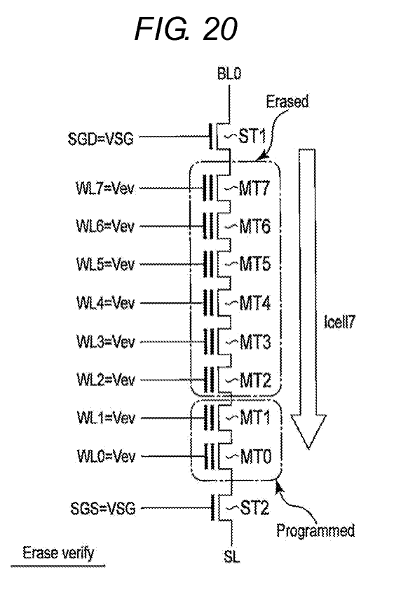

However, when the method is used, it is assumed that data is written in all of the pages (all of the word lines) in the string unit SU. In other words, when the program verification is performed, the condition of voltage is assuming that data is written in all of the pages. Therefore, if data is not written in all of the pages, it is not possible to realize the same condition when data is read, and thus there is a possibility that erroneous read occurs. In addition, when data is erased, large cell current Icell7 flows through the memory cell transistors MT2 to MT7 which are originally in the erase state as illustrated in FIG. 20, and thus there is a possibility that the memory cell transistors MT2 to MT7 passes the erase verification even when the written memory cell transistors MT0 and MT1 are not sufficiently erased.

At this point, in the 3-dimensional stacked NAND flash memory, the word lines are stacked on the upper side of the semiconductor substrate, and thus it is possible to remarkably improve the degree of integration, as compared to a planar NAND flash memory in which memory cells are 2-dimensionally formed. Instead, the number of pages which are included in a single string unit SU is significantly large. Therefore, for example, even when it is sufficient to write data in only a page corresponding to the word line WL1, it is necessary to write random data in all of remaining pages. However, it is useless to write the random data, and, accordingly, it takes time to write the random data.

Here, according to the embodiment, when data is read, the controller 200 provides the information indicative of a word line WL (page), up to which data is written, to the NAND flash memory 100. Further, the NAND flash memory 100 does not apply an equivalent voltage to all of the non-selected word lines WL, and applies an appropriate voltage to word lines WL corresponding to a written area and an unwritten area according to the received information. Therefore, it is not necessary to write useless data, it is possible to correctly read data, and it is possible to correctly erase the data. Furthermore, the data write operation can be shortened due to omitting of writing useless data.

More specifically, when the program verification is performed, VPVD which is lower than VREAD is applied to non-selected word lines which are on the further drain side than the selected word line (refer to FIG. 10). Further, when data is read thereafter, VPVD is applied to the word lines WL corresponding to the unwritten area, and VREAD is applied to the word line WL corresponding to the written area (refer to FIG. 12). That is, a relatively low voltage VPVD is applied to the gates of the memory cell transistors MT in the erase state which is easily turned on strongly, and a high voltage VREAD is applied to the gates of the memory cell transistors MT in which data is written and the thresholds thereof may be raised. Accordingly, even when write is ended in a page in the middle of the string unit SU, it is possible to set cell current Icell2, which flows when data is read to a value which is equivalent, to the cell current Icell1 which flows when the program verification is performed. Therefore, it is possible to prevent data from being erroneously read.

This is the same as when data is erased. For example, as illustrated in FIG. 15, when erase verification is performed, the relationship of voltages is set for the word lines WL0 to WL7 in that it is easy to turn on the memory cell transistors MT4 to MT7, which have been already in the erase state, when data is erased and it is hard to turn on the written memory cell transistors MT0 to MT3 which are completely written. Therefore, it is possible to sufficiently reduce the thresholds of the memory cell transistors MT0 to MT3. Otherwise, as illustrated in FIG. 16, when data is erased, the relationship of voltages is set for the word lines WL0 to WL7 in that it is relatively hard to reduce the thresholds of the memory cell transistors MT4 to MT7 which have been already in the erase state and it is easy to reduce the written memory cell transistors MT0 to MT3 which are completely written. Therefore, it is possible to correctly erase data.

As described above, the semiconductor memory device according to the embodiment includes a plurality of memory cells which are stacked on the upper side of a semiconductor substrate and connected in series, a plurality of word lines which are connected to the gates of the plurality of memory cells, and a row decoder which is connected to the plurality of word lines. When data is read, the row decoder transfers a first voltage (VPVD in FIG. 12) to non-selected word lines (WL4 to WL7 in FIG. 12) that are connected to unprogrammed memory cells, and transfers a second voltage (VREAD in FIG. 12), which is higher than the first voltage, to the non-selected word lines (WL0, WL2, and WL3 in FIG. 12) that are connected to the programmed memory cells. Meanwhile, the “unprogrammed memory cells” in the disclosure mean the memory cell transistors that include thresholds at the erase level after data is erased and the programming operation has not been performed yet. The memory cells in which “0” is written are the “programmed memory cells”. In addition, the memory cell transistors, in which data is written once but the data is erased thereafter and the data has not been rewritten yet, correspond to the “unprogrammed memory cells”.

### 6. MODIFICATION EXAMPLE

According to the above-described configuration, it is possible to improve the performance of the semiconductor memory device. However, an embodiment is not limited to the above-described embodiment, and various modifications are possible. For example, the write state table 270 is not limited to information as illustrated in FIG. 5 and may include information indicative of a page up to which data is written, in other words, a page which is in the erase state. In addition, the voltage which is applied to the word lines WL and which is described with reference to FIGS. 9, 10, 12, and 14 to 16 is an example, and the voltage is not limited thereto. That is, the voltage is not limited so long as cell current, which flows when program verification is performed, and the cell current, which flows when the program is read, become the same degree.

In addition, in the embodiment, although the case in which the size of the cell current is made an adjustment in both the write operation and the erase operation is described, a case in which either one of the operations is made an adjustment may be used.

In addition, in the example of FIG. 4, the case in which the NAND strings, to which the select gate line SGS is adjacent, are commonly connected to each other is described as an example. However, division may be performed on each select gate line SGS such that each select gate line SGS may be independently controlled.

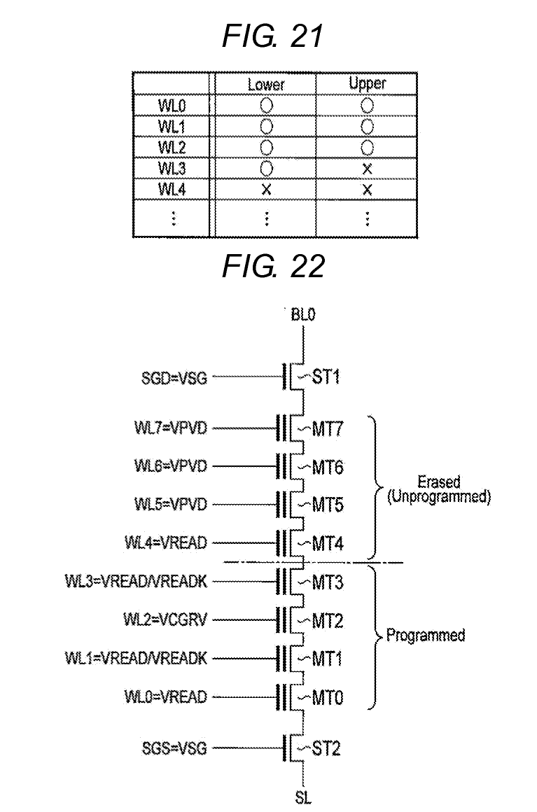

Further, when each of the memory cell transistors MT may hold multi-bit data (multi-level cell or MLC), the write state table 270 may hold information indicative of a bit up to which data is written. Further, a voltage which is applied to non-selected word lines may be determined according to the bit up to which data is written. Such an example will be described with reference to FIGS. 21 to 24. FIG. 21 is a schematic diagram illustrating information which is held in the write state table 270, and FIGS. 22 to 24 are circuit diagrams illustrating a NAND string acquired when data is read and illustrating examples in which the memory cell transistors MT may hold two-bit data.

As illustrated in FIG. 21, the write state table 270 holds, for example, information indicative of a word line (page) up to which data is written for each string unit. The example in FIG. 21 illustrates an example in which information indicative of whether only a lower bit is written or an upper bit is written for each word line is held. However, it is apparent that the example is not limited to such a table and FIG. 21 is only a schematic diagram illustrating information which is held in the table 270. In the example of FIG. 21, the word lines WL0 to WL2 are written up to the lower bit and the upper bit, and the word line WL3 is written up to only the lower bit.

FIG. 22 is a circuit diagram illustrating a NAND string in which the word line WL2 is selected when data is read, data is written up to the upper bit of the word line WL3, and word lines subsequent to the word line WL4 are in the erase state. In this case, VREAD or VREADK is applied to the word line WL3.

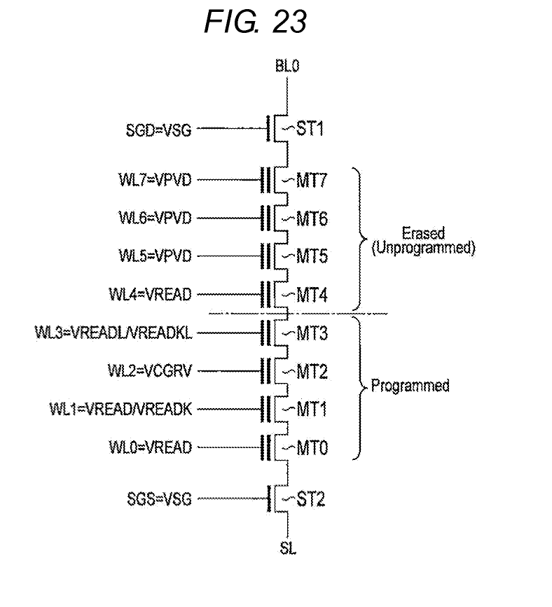

FIG. 23 is a circuit diagram illustrating the NAND string in which the word line WL2 is selected when data is read, data is written up to the lower bit of the word line WL3, and the word lines subsequent to the word line WL4 are in the erase state. In this case, VREADL or VREADKL is applied to the word line WL3. VREADL may have the same value as VREAD or may have a different value. VREADKL may have the same value as VREADK or may have a different value.

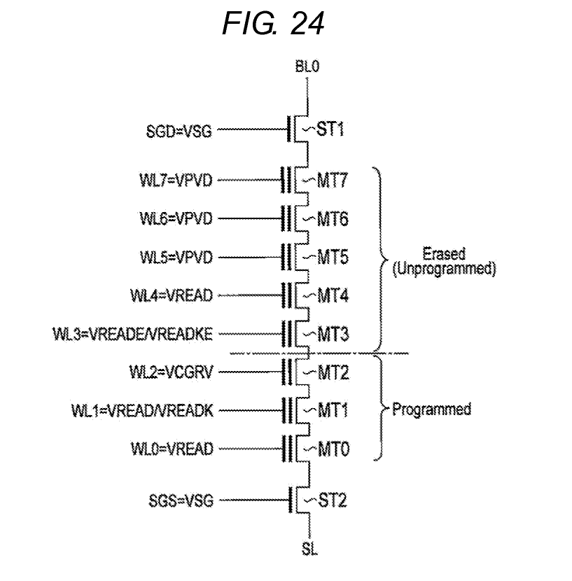

FIG. 24 is a circuit diagram illustrating the NAND string in which the word line WL2 is selected when data is read, data is written only up to the word line WL2, and the word lines subsequent to the word line WL3 are in the erase state. In this case, VREADE or VREADKE is applied to the word line WL3. VREADE may have the same value as VREAD and VREADL or may have a different value. VREADKE may have the same values as VREADK or may have a different value.

As described above, according to the embodiment, it is possible to input a word line (page), up to which data is written, to the NAND flash memory from the outside. Therefore, in a case of MLC, it is possible to input information indicative of the lower/upper page of the word line up to which data is written. Further, the sequencer 116 determines a voltage which is applied to each of the word lines WL based on the information. For example, as described above, when a word line WL(n+1) is not written at all, VREADE or VREADKE is applied. When the word line WL(n+1) is written up to the lower page, VREADL or VREADKL is applied. When the word line WL(n+1) is written up to the upper page, VREAD or VREADK is applied. It is apparent that, this is only an example, and different types of voltage control may be performed.

In addition, the following condition may be assumed. (a) One bit line BL is electrically connected to a plurality of memory strings in one block BLK. The memory strings includes at least a first memory string and a second memory string. (b) the write operation is performed for a first memory cell transistor MTk in the first memory string at first. A subsequent write operation is performed for a first memory cell transistor MTk in the second memory string. Next, the write operation is performed for a second memory cell transistor MT(k+1) in the first memory string and for a second memory cell transistor MT(k+1) in the second memory string in order. (c) data are written for the memory cell transistors MT0-MT5 in the first memory string. (d) data are written for the memory cell transistors MT0-MT4 in the second memory string.

In the above condition, we consider a case reading data from the memory cell transistor MT1 in the second memory string. The voltage VDGRV is applied to the selected word line WL1, the voltage VREADK is applied to unselected word lines WL0 and WL2, the voltage VPVD may be applied to unselected word line WL6 and WL7 only. And the voltage VREAD is applied to other unselected word lines.

In addition, the memory cell array 111 may be formed on the upper side of a peripheral circuit such as the row decoder 112 or the sense amplifier 113. That is, the peripheral circuit may be formed on the semiconductor substrate, the interlayer insulating film may be formed to cover the peripheral circuit, and the well region 20 may be formed on the interlayer insulating film. Otherwise, the well region 20 may be the semiconductor substrate. In this case, the row decoder 112 or the sense amplifier 113 is adjacent to the memory cell array 111 and formed on the semiconductor substrate.

Further, in the embodiment, the case of the 3-dimensional stacked NAND flash memory is described as an example. However, it is possible to apply the embodiment to a planar NAND flash memory. It is apparent that there may be a case in which each of the memory cell transistors MT holds data which is equal to or greater than 2 bits. The advantages of the embodiment are remarkable when the thresholds of the memory cell transistors MT become high by programming the memory cells.

Meanwhile, in each embodiment,

(1) for example, in a read operation of the memory cell transistors capable of holding 2-bit data which includes an “E” level, an “A” level, a “B” level, and a “C” level in the ascending order of thresholds, a voltage which is applied to a word line selected in the read operation at the A level is included in a range, for example, between 0 V to 0.55V. However, the voltage is not limited thereto and may be included in any one of ranges between 0.1 V to 0.24 V, 0.21 V to 0.31 V, 0.31 V to 0.4 V, 0.4 V to 0.5 V, and 0.5 V to 0.55 V.

A voltage, which is applied to the word line selected in the read operation at the B level, is included in a range, for example, between 1.5 V to 2.3 V. However, the voltage is not limited thereto, and the voltage may be included in any one of ranges, for example, between 1.65 V to 1.8 V, 1.8 V to 1.95 V, 1.95 V to 2.1 V, and 2.1 V to 2.3 V.

A voltage, which is applied to the word line selected in the read operation at the C level, is included in a range, for example, between 3.0 V to 4.0 V. The voltage is not limited thereto, and the voltage may be included in any one of ranges between 3.0 V to 3.2 V, 3.2 V to 3.4 V, 3.4 V to 3.5 V, 3.5 V to 3.6 V, and 3.6 V to 4.0 V.

A time (tR) for the read operation may be in ranges, for example, between 25 μs to 38 μs, 38 μs to 70 μs and 70 μs to 80 μs.

(2) A write operation includes a programming operation and a verification operation as described above. In the write operation, a voltage, which is initially applied to a word line selected when the programming operation is performed, is included in a range, for example, between 13.7 V to 14.3 V. The voltage is not limited thereto, and may be included in any one of ranges, for example, between 13.7 V to 14.0 V and 14.0 V to 14.6 V.

A voltage, which is initially applied to the selected word line when write is performed on odd-numbered word lines, and the voltage, which is initially applied to the selected word line when write is performed on even-numbered word lines, may be changed.

When an Incremental Step Pulse Program (ISPP) method is used for the programming operation, for example, approximately 0.5 V may be used as an example of a step-up voltage.

The voltage which is applied to the non-selected word lines may be included in a range, for example, between 6.0 V to 7.3 V. The voltage is not limited thereto and the voltage may be included in a range, for example, between 7.3 V to 8.4 V or may be equal to or lower than 6.0 V.

A pass voltage to be applied may be changed based on whether the non-selected word lines are the odd-numbered word lines or the even-numbered word lines.

A time (tProg) for the write operation may be included in ranges, for example, between 1,700 μs to 1,800 μs, 1,800 μs to 1,900 μs, and 1,900 μs to 2,000 μs.

(3) In the erase operation, the voltage which is initially applied to the well, which is formed on the upper section of the semiconductor substrate and of which the memory cells are arranged on the upper side, is included in a range, for example, between 12 V to 13.6V. The voltage is not limited thereto and may be included in ranges, for example, between 13.6 V to 14.8 V, 14.8 V to 19.0 V, 19.0 to 19.8 V, and 19.8 V to 21 V.

A time (tErase) for the erase operation may be included in ranges, for example, between 3,000 μs to 4,000 μs, 4,000 μs to 5,000 μs, and 4,000 μs to 9,000 μs.

(4) The memory cells are configured to include a charge storage layer which is arranged on a semiconductor substrate (silicon substrate) while interposing a tunnel insulating film, which has a film thickness of 4 to 10 nm, therebetween. It is possible for the charge storage layer to have a stacked structure of an insulating film, such as SiN or SiON which has a film thickness of 2 to 3 nm and a ploy-silicon which has a film thickness of 3 to 8 nm. In addition, metal, such as Ru, may be added to poly-silicon. The insulating film is provided on the charge storage layer. The insulating film includes, for example, a silicon nitride film which has a film thickness of 4 to 10 nm and which is interposed between a lower layer High-k film having a film thickness of 3 to 10 nm and an upper layer High-k film having a film thickness of 3 to 10 nm. HfO or the like may be an example of the High-k film. In addition, it is possible to cause the film thickness of the silicon nitride film to be thicker than the film thickness of the High-k film. A control electrode which has a film thickness of 30 nm to 70 nm is formed on the insulating film while interposing a work function adjusting material, which has a film thickness of 3 to 10 nm, therebetween. Here, the work function adjusting material is a metal-oxide film, such as TaO, or a metal nitride film such as TaN. It is possible to use W or the like for the control electrode.

In addition, it is possible to form air gaps between the memory cells.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a plurality of memory cells that are stacked above a semiconductor substrate and are electrically connected in series, the memory cells including first memory cells that are in an erased state and second memory cells that are in a programmed state;
a plurality of word lines that are electrically connected to gates of the memory cells; and
a row decoder that is electrically connected to the word lines, wherein
when data is read from a group of memory cells, the row decoder selects a word line electrically connected to gates of the memory cells in the group, transfers a read voltage to the selected word line, transfers a first voltage to non-selected word lines that are electrically connected to gates of the first memory cells, and transfers a second voltage, which is different from the first voltage, to non-selected word lines that are electrically connected to the second memory cells.

2. The device according to claim 1, wherein
the first voltage is at a same voltage level as a program verification voltage that is applied to memory cells that are programmed.

3. The device according to claim 2,
wherein the second voltage is higher than the first voltage.

4. The device according to claim 1, further comprising:
a register in which information indicating the word lines connected to the second memory cells is stored.

5. The device according to claim 4, wherein the register also stores therein a command and an address at which the command is to be executed.

6. The device according to claim 5, further comprising:
a control unit configured to control the row decoder to transfer the first or second voltage to the non-selected word lines according to the information stored in the register.

7. The device according to claim 6, wherein the control unit is a sequencer.

8. The device according to claim 1, further comprising:
first and second select transistors electrically connected in series to opposite ends of the plurality of memory cells, such that the memory cells are between the first select transistor and the semiconductor substrate and the second select transistor is between the memory cells and the semiconductor substrate.

9. The device according to claim 8, further comprising:
a bit line, wherein a first end of the first select transistor is electrically connected to the bit line and a second end of first select transistor is electrically connected to the memory cells; and
a source line, wherein a first end of the second select transistor is electrically connected to the source line and a second end of second select transistor is electrically connected to the memory cells.

10. A semiconductor memory device comprising:
a plurality of memory cells that are stacked above a semiconductor substrate and are electrically connected in series, the memory cells including first memory cells that are in an erased state and second memory cells that are in a programmed state;
a plurality of word lines that are electrically connected to gates of the memory cells; and
a row decoder that applies a voltage to the word lines, wherein
when the memory cells are erased or erase verification is performed on the memory cells, the row decoder transfers a first voltage to word lines that are electrically connected to the first memory cells, and transfers a second voltage, which is different from the first voltage, to word lines which are electrically connected to the second memory cells.

11. The device according to claim 10,
wherein the first voltage is higher than the second voltage.

12. The device according to claim 10, further comprising:
a register in which information indicating the word lines connected to the first memory cells is stored.

13. The device according to claim 12, wherein the register also stores therein a command and an address at which the command is to be executed.

14. The device according to claim 13, further comprising:
a control unit configured to control the row decoder to transfer the first or second voltage to the word lines according to the information stored in the register.

15. The device according to claim 14, wherein the control unit is a sequencer.

16. The device according to claim 10, further comprising:
first and second select transistors electrically connected in series to opposite ends of the plurality of memory cells, such that the memory cells are between the first select transistor and the semiconductor substrate and the second select transistor is between the memory cells and the semiconductor substrate.

17. The device according to claim 16, further comprising:
a bit line, wherein a first end of the first select transistor is electrically connected to the bit line and a second end of first select transistor is electrically connected to the memory cells; and
a source line, wherein a first end of the second select transistor is electrically connected to the source line and a second end of second select transistor is electrically connected to the memory cells.

18. A memory controller that controls a semiconductor memory device in which data is written in units of a page, comprising:
a memory unit that stores a table that holds information indicating states of pages as being programmed or erased; and
a control unit configured to issue a command, wherein
the control unit, before issuing the command, transmits information held in the table to the semiconductor memory device.

19. The controller according to claim 18, wherein the command is a read command.

20. The controller according to claim 18, wherein the command is an erase command.
